(19) United States
(12) Patent Application Publication
(10) Pub. No.: US 2008/0186037 A1
(43) Pub. Date: Aug. 7, 2008

(54) PROBE CARD AND STRUCTURE FOR FIXING NEEDLE THEREOF

(75) Inventor: Ki Don Ko, Gyeonggi-do (KR)

Correspondence Address: PEARNE & GORDON LLP, 1801 EAST 9TH STREET, SUITE 1200, CLEVELAND, OH, 44114-3108, US

(73) Assignee: WILLTECHNOLOGY CO., LTD., Gyeonggi-do (KR)

(21) Appl. No.: 12/026,784

(22) Filed: Feb. 6, 2008

(30) Foreign Application Priority Data
Feb. 7, 2007 (KR) 10-2007-0012759

(51) Int. Cl. G01R 1/067; B23P 19/04

(52) U.S. Cl. 324/754; 29/747

(57) ABSTRACT

A probe card having a simple structure and an easy manufacturing process is disclosed. The probe card includes an upper structure having a probe circuit pattern, and a needle having an elastic bending portion, a tip portion extending from a lower end of the elastic bending portion, and a connection portion extending from an upper end of the elastic bending portion and connected electrically to the probe circuit pattern. Here, a portion of the elastic bending portion is received in the upper structure.

### FIELD OF THE INVENTION

The present disclosure relates to a probe card needed for a semiconductor testing apparatus. More particularly, the present invention relates to a needle and a probe card having the same, which can reduce the manufacturing cost with improved workability and productivity and provide easy maintenance and repair by simplifying a structure and manufacturing process.

### BACKGROUND OF THE INVENTION

Generally, a semiconductor device is manufactured through a fabrication process for forming a pattern on a wafer and an assembly process for assembling the patterned wafer into packaged chips.

In order to detect defective chips in the wafer, an electrical die sorting (EDS) process for testing the electrical characteristics of the respective chips in the wafer, which intervenes between the fabrication process and the assembly process, is performed. The EDS process is mainly performed by a testing apparatus applying electrical signals to the chips constituting the wafer and detects the defective chips based on the signals returned from the chips in response to the applied electrical signals.

The EDS process is mainly performed by the testing apparatus called a probe card having a plurality of needles that apply the electrical signals to the pattern of the respective chips while contacting with the pattern. More particularly the electrical characteristic test of the chips in the semiconductor wafer is typically performed in a manner that the needles of the probe card are to be in contact with electrode pads or circuit terminals of the chips in the semiconductor wafer, and predetermined current is applied through the needles to test the electrical characteristics of the respective chips.

If it is checked that the chips in the wafer are normal through the above test using the probe card, the manufacture of the semiconductor device is completed through an assembly process such as packaging and so on.

FIG. 1 is a sectional view illustrating the structure of a conventional probe card.

As shown in FIG. 1, the probe card 20 includes a main substrate 30 on which a probe circuit pattern is formed and a plurality of needles 50 mounted on a lower surface of the main substrate 30 so as to vertically contact with a plurality of electrode pads (or circuit terminals) formed on a wafer 10 as a test object. Further, each of the needles 50 is supported and disposed by a needle fixing block 40 that is fixedly installed on the lower surface of the main substrate 30 in a state that the needles 50 are electrically connected to the main substrate 30.

The needle fixing block 40 includes a connection plate 42 disposed apart from the lower surface of the main substrate 30 by a predetermined distance, and a tip plate 44 disposed apart from a lower surface of the connection plate 42. Each of the plates 42 and 44 is disposed in parallel to the main substrate 30. A fastening: member 45 is fixed to the main substrate 30 through the plates 42 and 44 such that the alignment between the main substrate 30, the connection plate 42 and the tip plate 44 is maintained.

Each of the needles 50 passes through the connection plate 42 and the tip plate 44. One end of the needle 50 is extended to the main substrate 30, thereby being electrically connected to the probe circuit pattern of the main substrate 30 through a wire 32 fixed by soldering, and the other end of the needle 50 is extended to a lower surface of the tip plate 44 and projected to an outside of the needle fixing block 40 so that the needle 50 is in contact with the test object. Guide holes 42a, 44a and 31 are formed through the respective plates 42, 44 and the main substrate 30 so that the needle 50 passes through the guide holes 42a, 44a and 31. The guide holes 42a, 44a and 31 corresponding to the needle 50 are arranged on the same line. Also, the disposition of the needles 50 is firmly kept by a resin layer 46 made of epoxy and so on and to be formed on an upper surface of the connection plate 42.

In addition, in the center portion of the respective needle 50 that is disposed between the connection plate 42 and the tip plate 44, a bending portion 52 is formed such that the respective needle 50 elastically contacts the test object.

However, since the disposition of the needles 50 are maintained and fixed by a separate resin layer 46 formed on the upper surface of the connection plate 42 in the probe card 20, the number of elements of the probe card 20 and the number of steps of manufacturing the probe card 20 are increased, and this causes the manufacturing cost to increase with the workability and productivity degraded.

In addition, in order to maintain and fix the needle 50, the tip plate 44 is separately disposed apart from the connection plate 42 so that the guide hole 44a, through which the needle 50 passes, is formed through the tip plate 44.

That is, in accordance with the conventional probe card, the separate resin layer 46 formed on the upper surface of the connection plate 42 and the tip plate 44 should be required so as to maintain and fix the disposition of the needle 50. Moreover, a fixing means, such as a jig for temporarily fixing the needle 50 disposed on the needle fixing block 40 before the resin layer 46 is formed, is required.

On the other hand, numerous needles are needed for the purpose of testing a test object such as a semiconductor wafer having numerous sub-test objects. These needles may be deformed due to stress caused by repeated load generated during the testing process, or may not be used due to abrasion. The deformed or abraded needles should be easily replaced so as to prevent a case that the expensive probe card cannot be used due to several deformed or abraded needles among the numerous needles.

However, since the needles 50 of the conventional probe card 20 are fixedly maintained by the resin layer 46 formed on the upper surface of the connection plate 42 and the tip plate 44, and an upper end of the each needles is connected to the probe circuit pattern of the main substrate 30 through a wire 32 by soldering, it is difficult to maintain and repair the needles 50.

Specifically, in order to replace the deformed or abraded needles in the probe card 20, the connection of normal needles with the wires as well as the connection of the deformed or abraded needles with the wires 32 should be released. Thereafter, the resin layer 46 and the plates 42 and 44 are removed, and then the deformed or abraded needles are replaced. Consequently, in accordance with the conventional prove card 20, the above repairing process should be performed even with respect to other normal needles as well as the several deformed or abraded needles. Accordingly, much manpower and time are required to maintain and repair the probe card 20, and the cost for the maintenance and repair of the probe card 20 is increased.

### BRIEF SUMMARY OF THE INVENTION

In view of the foregoing, the present invention has been made to solve the above-mentioned problems occurring in the prior art, and an object of the present invention is to provide a needle and a prove card, in which each needle can be fixed to the prove card by binding only one end part of the needle without the necessity of binding both end parts of the needle.

Another object of the present invention is to provide a needle and a probe card, which does not greatly depend on the accuracy of upper and lower structures of the probe card even though both parts of each needle are bound.

Still another object of the present invention is to provide a needle and a probe card, which can prevent elastic bending parts of needles from being in contact with each other or interfering with each other.

Still another object of the present invention to provide a probe card which can reduce the manufacturing cost with improved workability and productivity by reducing the number of elements and manufacturing steps.

Still another object of the present invention is to provide a probe card which can provide easy maintenance and repair, and thus reduce manpower and time for the maintenance and repair.

Still another object of the present invention to provide to diverse needles which can reduce the manufacturing cost with improved workability and productivity by fixing the disposition state of the needles and reducing the number of elements and manufacturing steps.

In accordance with an embodiment of the present invention, there is provided a probe card including a probe circuit pattern; and a needle including an elastic bending portion, a tip portion extending from a lower end of the elastic bending portion, and a connection portion extending from an upper end of the elastic bending portion and connected electrically to the probe circuit pattern, wherein at least a part of the elastic bending portion is received in the upper structure.

The elastic bending portion includes a convex portion having a curve shape or a bending shape.

A connection portion axis along the connection portion and a tip portion axis along the tip portion axis are on a same line or apart from each other.

The upper structure includes a guide hole through which the connection portion passes and a needle fixing groove receives the at least a part of the portion of the elastic bending portion.

The guide hole is connected to the needle fixing groove.

At least a part of a changeover portion for connecting the connection portion to the elastic bending portion is received in the needle fixing groove.

The upper structure includes a guide hole through which the connection portion passes, and the guide hole is separately formed apart from the needle fixing groove.

The changeover portion for connecting the connection portion to the elastic bending portion is located below the guide hole, and at least a part of the elastic bending portion upwardly following the changeover portion is received in the needle fixing groove.

The upper structure further includes a tip plate which is apart from the connection plate and is disposed in parallel to the connection plate.

In accordance with another embodiment of the present invention, there is provided a structure for fixing a needle of a probe card including an upper structure including a probe circuit pattern; a connection plate located below the upper structure and having a needle fixing groove formed on a lower surface thereof; and the needle having an elastic bending portion, a tip portion extending from a lower end of the elastic bending portion, and a connection portion extending from an upper end of the elastic bending portion and connected electrically to the probe circuit pattern, wherein a distance between a outmost portion of the elastic bending portion and an tip portion axis is greater than a distance between the outmost portion of the elastic bending portion and an axis corresponding to the connection portion.

The upper structure contains a guide hole through which the connection portion passes, and the guide hole is connected to the needle fixing groove.

At least a part of a changeover portion for connecting the connection portion to the elastic bending portion is received in the needle fixing groove.

The upper structure contains a guide hole through which the connection portion passes, and the guide hole is separately formed apart from the needle fixing groove.

The changeover portion for connecting the connection portion to the elastic bending portion is located below the guide hole, and at least a part of the elastic bending portion upwardly following the changeover portion is received in the needle fixing groove

### BRIEF DESCRIPTION OF THE DRAWINGS

The disclosure may best be understood by reference to the following description taken in conjunction with the following figures:

FIG. 1 is a sectional view illustrating the structure in accordance with a conventional probe card;

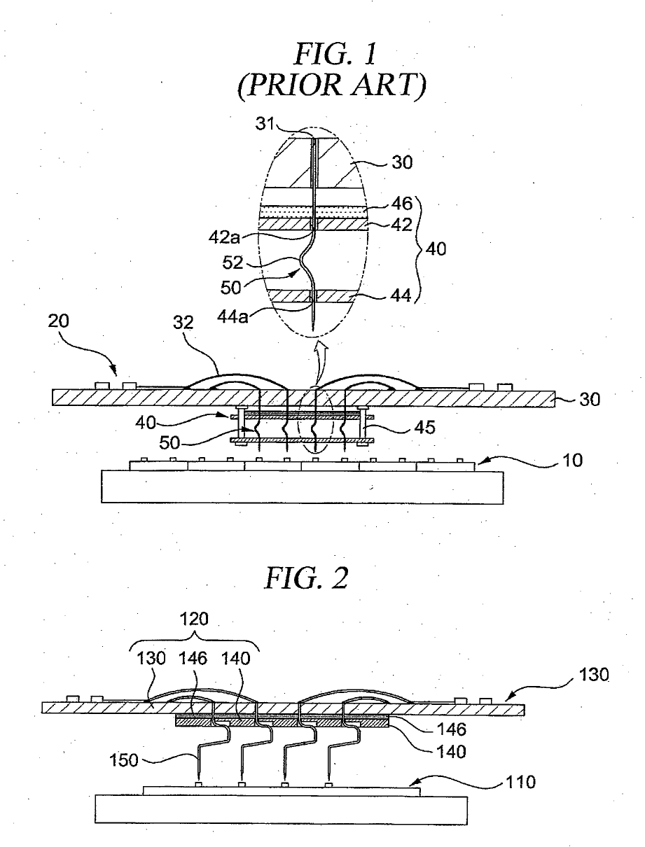

FIG. 2 is a sectional view illustrating the structure of a probe card in accordance with an embodiment of the present invention;

FIGS. 3 and 4 are respectively a sectional view and an enlarged view illustrating the structure and an installation structure of a needle in a probe card in accordance with the embodiment of the present invention;

FIG. 5 is a sectional view illustrating a needle in accordance with another embodiment of the present invention;

FIG. 6 is a sectional view illustrating the structure of a probe card in accordance with still another embodiment of the present invention; and

FIGS. 7 and 8 are respectively a sectional view and an enlarged view illustrating the structure and an installation structure of a needle in a probe card in accordance with still another embodiment of the present invention

### DETAILED DESCRIPTION OF THE INVENTION

Hereinafter, embodiments of the present invention will be described in detail with reference to the accompanying drawings so that the present invention may be readily implemented by those skilled in the art. However, it is to be noted that the present invention is not limited to the embodiments but can be realized in various other ways. In the drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element. Further, the term “comprises or includes” and/or “comprising or including” used in the document means that one or more other components, steps, operation and/or existence or addition of elements are not excluded in addition to the described components, steps, operation and/or elements.

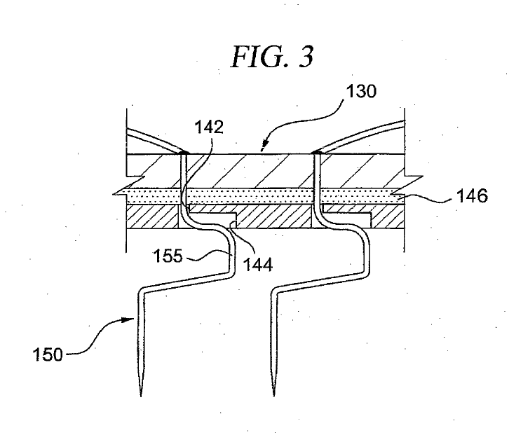

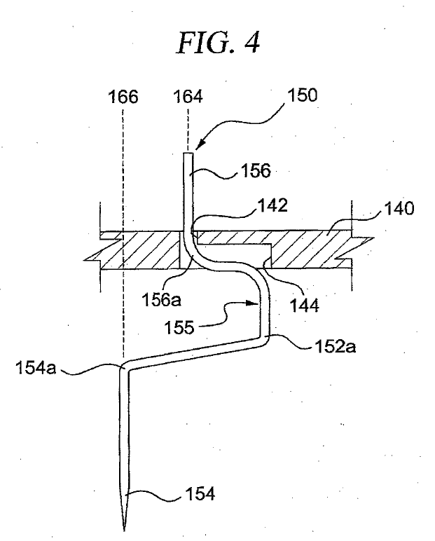

FIG. 2 is a sectional view illustrating the structure of a probe card in accordance with an embodiment of the present invention. FIGS. 3 and 4 are respectively a sectional view and an enlarged view illustrating the structure and an installation structure of a needle in a probe card in accordance with the embodiment of the present invention.

As shown in FIGS. 2 to 4, the probe card may vertically contact with a plurality of electrode pads (or circuit terminals) disposed on a wafer 110, which is a test object, and may be connected to the electrode pads to test the electrical characteristics of chips formed on the wafer 110. The probe card includes an upper structure 120 having a probe circuit pattern 130 and a plurality of needles 150. In accordance with the embodiment of the present invention, the needle 150 has an elastic bending portion 155, a tip portion 154 extending from a lower end of the elastic bending portion 155, and a connection portion 156 extending from an upper end of the elastic bending portion 155. Here, the connection portion 156 is electrically connected to the probe circuit pattern 130.

The upper structure 120 has a connection plate 140 mounted on a lower surface of a printed circuit board containing the probe circuit pattern 130 formed thereon. The connection plate 140 supports or fixes the needles 150. A resin layer 146 made of epoxy and so on, is formed on the connection plate 140 so as to maintain the needles 150 fixedly.

The needle 150 is supported and fixed by the connection plate 140. Here, an upper end of the needle 150 is electrically connected to the probe circuit pattern 130, and a lower end of the needle 150 vertically contacts with the wafer 110.

The elastic bending portion 155 is elastically moved when the tip portion 154 contacts with the test object, and thus the probing of the tip portion 154 is elastically performed. The elastic bending portion 155 help the needle 150 to be supported and fixed on the connection plate 140 as well as to contact the test object elastically.

In the needle 150, virtual axes along the connection portion 156 and the tip portion 154 (hereinafter referred to as “connection portion axis” and “tip portion axis”) are formed, and the connection portion axis 164 and the tip portion axis 166 are apart from each other for a predetermined distance. The elastic bending portion 155 is convexed so that a distance between the outmost portion 152a of the elastic bending portion 155 and the tip portion axis 166 is greater than a distance between the outmost portion 152a and the connection portion axis 164. This needle 150 performs the characteristic test of the object in a state where the needle 150 is supported and fixed by the connection plate 140 as described above.

A guide hole 142 for receiving the connection portion 156 of the needle 150 is formed through the connection plate 140. Here, the connection portion 156 extends from the elastic bending portion 155 through the guide hole 142, and is electrically connected to the probe circuit pattern 130.

A needle fixing groove 144, which receives at least a part of the elastic bending portion 155 extending from the guide hole 142, is formed on the lower surface of the connection plate 140. A combination of the guide hole 142 and the needle fixing groove 144 may have an “L” shape or an inverse “T” shape. For example, the connection portion 156 is received in a vertical part of the “L” shape, and the at least a part of the elastic bending portion 155 is received in a horizontal part of the “L” shape. Here, a changeover portion 156a for connecting the connection portion 156 to the elastic bending portion 155 is also received in the horizontal part of the “L” shape.

Since the at least a part of the elastic bending portion 155 is received in the needle fixing groove 144 of the upper structure 120, the needle 150 may be fixed to the upper structure 120 with a predetermined pose and location even though a lower structure does not exist. That is, the changeover portion 156a and the part of the elastic bending portion 155 are received within the needle fixing groove 144 so that vertical and horizontal movement of the needle 150 can be corrected when the needle 150 moves within the needle fixing groove 144. As a result, since the changeover portion 156a and the elastic bending portion 155 can move only within a given space, i.e., the needle fixing groove 144, the changeover portion 156a and the elastic bending portion 155 maintain the whole movement of the needle 150 with the predetermined pose and location. In addition, the movement of the respective needles 150, which becomes in contact with the test object, can be predetermined. Accordingly, unpreferable contact or interference between the elastic bending portions 155 of the needles 150 may be prevented, and thus the characteristic test may be accurately performed.

Of course, in accordance with an embodiment of the present invention, a lower structure having a guide hole may be further provided so that the lower end of the needle 150 can be received. However, even in this case, since the disposition and the movement of the needles 150 can be sufficiently maintained by the upper structure 120 only, the guide holes is not necessarily processed with high accuracy. Accordingly, the probe card having the needle 150, of which the elastic bending portion 155 is received in the needle fixing groove 144, may not have the lower structure, e.g., the conventional tip plate, and thus the cost required to manufacturing the tip plate can be considerably reduced.

Further, since only the upper structure 120 having the connection plate 140 is required, a process of manufacturing the probe card can be simplified, and thus workability and productivity are improved.

In addition, in the case where the repair or replacement is required for the needles 150, the repair or replacement is performed only for the upper structure 120. As a result, the maintenance for the probe card is easily performed, and thus the required resources can be reduced.

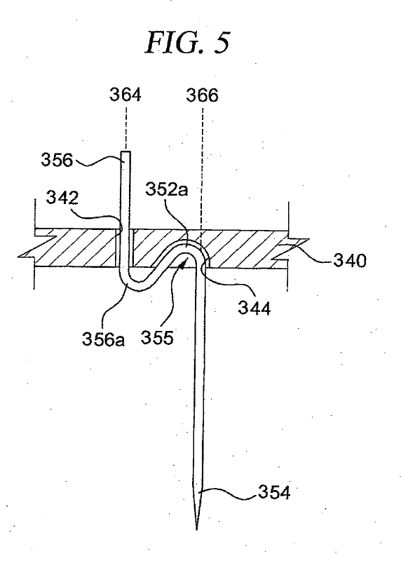

FIG. 5 is a sectional view illustrating a needle in accordance with another embodiment of the present invention.

As shown in FIG. 5, a guide hole 342 and a needle fixing groove 344 are formed on a connection plate 340. A needle 350 in accordance with another embodiment of the present invention has a connection portion 356 electrically connected to a probe circuit pattern 130 through the guide hole 142, an elastic bending portion 355, and a tip portion 354.

In order to support and fix the needle 150, the guide hole 342 is formed through the connection plate 344 and the needle fixing groove 344 are formed on a lower surface of the connection plate 340. The connection portion 356 of the needle 350 is electrically connected to the probe circuit pattern 330 through the guide hole 342. The needle fixing groove 344 is apart from the guide hole 342 and receives the elastic bending portion 355.

That is, the needle fixing groove 344 is separately formed apart from the guide hole 342. A changeover portion 356a for connecting the connection portion 356 to the elastic bending portion 355 is located below the connection plate 140.

In accordance with another embodiment of the present invention, a connection portion axis 364 along the connection portion 356 and a tip portion axis 366 along the tip portion 354 may be apart from each other for a predetermined distance. In addition, the changeover portion 356a for connecting the connection portion 356 to the elastic bending portion 355 may not be received in the connection plate 340 but be formed below the connection plate 340.

A outmost portion 352a of the elastic bending portion 355 is received within the needle fixing groove 344, which is formed on the lower surface of the connection plate 340. In accordance with another embodiment of the present invention, the outmost portion 352a of the elastic bending portion 355 has an inverse “U” shape, and the tip portion 354 downwardly extends from the outmost portion 352a. As a result, since the at least a part of the elastic bending portion 355 is received in the needle fixing groove 344 of the upper structure 320, the needle 350 may be fixed to the upper structure 320 with a predetermined pose and location even though a lower structure does not exist. That is, the changeover portion 356a and the at least the part of the elastic bending portion 355 are received within the needle fixing groove 344 so that vertical and horizontal movement of the needle 350 can be corrected when the needle 350 moves within the needle fixing groove 344. Accordingly, since the changeover portion 356a and the elastic bending portion 355 can move within a given space, i.e. the needle fixing groove 344, the changeover portion 356a and the elastic bending portion 355 maintain the whole movement of the needle 350 having the predetermined pose and location.

Moreover, the movement of the respective needles 350, which becomes in contact with the test object, can be predetermined. Accordingly, unpreferable contact or interference between the elastic vending portions 355 of the needles 350 may be prevented, and thus the characteristic test may be accurately performed.

In accordance with another embodiment of the present invention, a lower structure having a guide hole may be further provided so that the lower end of the needle 350 can be received. However, even in this case, since the disposition and the movement of the needles 350 can be sufficiently maintained by the upper structure 320 only, the guide holes of the lower structure is not necessarily processed with high accuracy. Accordingly, the probe card having the needle 350, of which the elastic bending portion 355 is received in the needle fixing groove 344, may not have the lower structure, e.g., the conventional tip plate, and thus the cost required to manufacturing the tip plate can be reduced.

Further, since only the upper structure 320 having the connection plate 340 is necessarily required, a process of manufacturing the probe card can be simplified, and thus workability and productivity are improved.

In addition, in the case where the repair or replacement is required for the needles 350, the repair or replacement is required only for the upper structure 320. As a result, the maintenance for the probe card is easily performed, and thus the required resources can be reduced.

In accordance with another embodiment of the present invention, it is exemplified that one plate 340 provided with the needle fixing groove 344 is formed so that the needle 350 is fixed and supported. However, a tip plate apart from and in parallel to the connection plate 340 may be further provided.

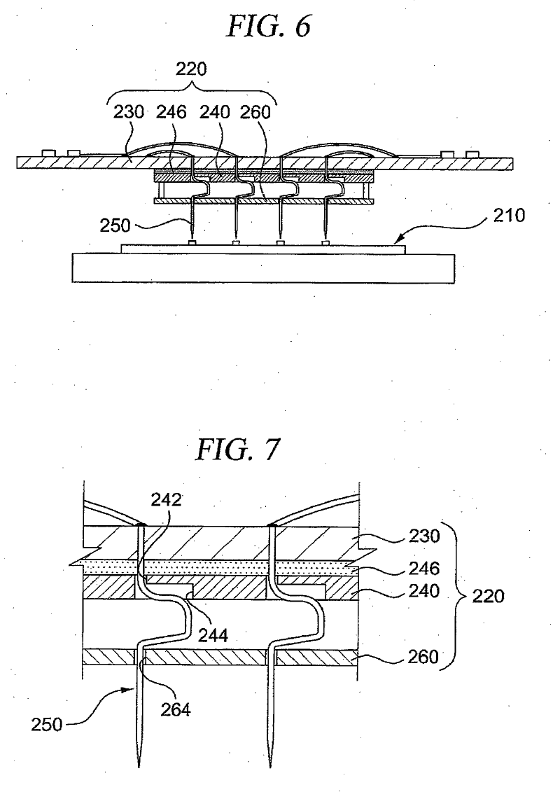

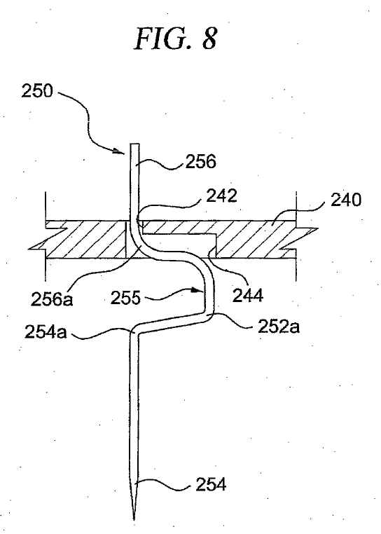

FIG. 6 is a sectional view illustrating the structure of a probe card in accordance with still another embodiment of the present invention. FIGS. 7 and 8 are a sectional view and an enlarged view illustrating the structure and an installation structure of a needle in a probe card in accordance with still another embodiment of the present invention.

As shown in FIGS. 6 to 8, the probe card may vertically contact with a plurality of electrode pads (or circuit terminals) formed on a wafer 210 as a test object. The probe card includes an upper structure 220 having a probe circuit pattern 230 and a plurality of needles 250, and thus each of the needles 250 becomes in contact with the electrode pads so as to perform the electrical characteristic test of chips formed on the wafer 110. The needle 250 has an elastic bending portion 255, a tip portion 254 extending from a lower end of the elastic bending portion 255, and a connection portion 256 extending from an upper end of the elastic bending portion 255. Here, the connection portion 256 is electrically connected to the probe circuit pattern 230.

The upper structure 220 has a connection plate 240 mounted on a lower surface of a printed circuit board containing the probe circuit pattern 230 formed thereon. The connection plate 240 supports or fixes the needles 250. A resin layer 246 made of epoxy and so on is formed on the connection plate 240 so as to fix the needles 150.

The needle 250 is supported and fixed by the connection plate 240. Here, an upper end of the needle 250 is electrically connected to the probe circuit pattern 230, and a lower end of the needle 250 vertically contacts with the wafer 210.

The elastic bending portion 255 is elastically moved when the tip portion 254 contacts with the test object, and thus the probing of the tip portion 254 is elastically performed. The elastic bending portion 255 help the needle 250 to be supported and fixed on the connection plate 240 as well as to contact the test object elastically.

With regard to the needle 250, the connection portion 256 and the tip portion 254 are coaxially formed on the same line. In addition, a tip plate 260 having a guide hole 264 for receiving the tip portion 254 of the needle 250 is provided.

The guide hole 242 is formed through the connection plate 240 so that the connection portion 256 of the needle 250 passes through the guide hole 242. The connection portion 256 extending from the elastic bending portion 255 passes through the guide hole 242, and thus being electrically connected to the probe circuit pattern 230.

The tip portion 254 extends from the lower end of the elastic bending portion 255, and thus projects over a lower surface of the tip plate 260. The tip portion 254 becomes in contact with a wafer as the test object in state where the characteristic test is performed.

A needle fixing groove 244, which receives at least a part of the elastic bending portion 255 connected to the guide hole 242, is formed on the lower surface of the connection plate 240. A combination of the guide hole 242 and the needle fixing groove 244 may have an “L” shape or an inverse “T” shape. For example, the connection portion 256 passes through a vertical part of the “L” shape, and the elastic bending portion 255 is received in a horizontal part of the “L” shape. Here, a changeover portion 256a for connecting the connection portion 256 to the elastic bending portion 255 is also received in the horizontal part of the “L” shape.

Since at least a part of the elastic bending portion 255 is received in the needle fixing groove 244 of the upper structure 220, the needle 250 may be fixed to the upper structure 220 with a predetermined pose and location even though a lower structure does not exist. That is, the changeover portion 256a and the at least part of the elastic bending portion 255 are received within the needle fixing groove 244 so that vertical and horizontal movement of the needle 250 can be corrected when the needle 150 moves within the needle fixing groove 244. As a result, since the changeover portion 256a and the elastic bending portion 255 can move only within a given space, i.e. the needle fixing groove 244, the changeover portion 256a and the elastic bending portion 255 maintain the whole movement of the needle 250 having the predetermined pose and location. In addition, the movement of the respective needles 250, which becomes in contact with the test object, can be predetermined. Accordingly, unpreferable contact or interference between the elastic vending portions 255 of the needles 250 may be prevented, and thus the characteristic test may be accurately performed.

In accordance with still another embodiment of the present invention, a lower structure having a guide hole may be further provided so that the lower end of the needle 250 can be received. However, even in this case, since the disposition and the movement of the needles 250 can be sufficiently maintained by the upper structure 220 only, the guide holes is not necessarily processed with high accuracy.

Further, since only the upper structure 220 having the connection plate 340 is necessarily required, a process of manufacturing the probe card can be simplified, and thus workability and productivity are improved.

In addition, in a state where the repair or replacement is required for the needles 350, the repair or replacement is required only for the upper structure. As a result, the maintenance for the probe card is easily performed, and thus the required resources can be reduced.

As described above, in accordance with the needle and the probe card having the same in accordance with the present invention, each needle can be fixed to the prove card by binding only one end portion of the needle without the necessity of binding both end portions of the needle.

Also, the prove card in accordance with the present invention does not greatly depend on the accuracy of lower structures of the probe card even though both portions of each needle are bound.

Also, the probe card in accordance with the present invention can prevent elastic bending portions of needles from being in contact with each other or interfering with each other.

Also, the probe card in accordance with the present invention can reduce the manufacturing cost with improved workability and productivity by reducing the number of elements and manufacturing steps.

Also, the probe card in accordance with the present invention can provide easy maintenance and repair, and thus reduce manpower and time required for the maintenance and repair.

Also, the probe card in accordance with the present invention can provide the needles, which can be disposed and fixed with improved workability and productivity, so that the number of elements and manufacturing steps and the manufacturing cost are reduced.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A probe card comprising:
an upper structure including a probe circuit pattern; and
a needle including an elastic bending portion, a tip portion extending from a lower end of the elastic bending portion, and a connection portion extending from an upper end of the elastic bending portion and connected electrically to the probe circuit pattern,
wherein at least a part of the elastic bending portion is received in the upper structure.

2. The probe card of claim 1, wherein the elastic bending portion is convexed in a curve shape or a bending shape.

3. The probe card of claim 1, wherein a connection portion axis along the connection portion and a tip portion axis along the tip portion are on a same line or apart from each other.

4. The probe card of claim 1, wherein the upper structure includes a guide hole through which the connection portion passes and a needle fixing groove receives at least a part of the portion of the elastic bending portion.

5. The probe card of claim 4, wherein the guide hole is connected to the needle fixing groove.

6. The probe card of claim 4, wherein the at least a part of a changeover portion for connecting the connection portion to the elastic bending portion is received in the needle fixing groove.

7. The probe card of claim 1, wherein the upper structure includes a guide hole through which the connection portion passes, and the guide hole is separately formed apart from the needle fixing groove.

8. The probe card of claim 7, wherein a changeover portion for connecting the connection portion to the elastic bending portion is located below the guide hole, and at least a part of the elastic bending portion upwardly following the changeover portion is received in the needle fixing groove.

9. The probe card of claim 1, wherein the upper structure further includes a tip plate which is apart from the connection plate and is disposed in parallel to the connection plate.

10. A structure for fixing a needle of a probe card comprising:
an upper structure including a probe circuit pattern;
a connection plate located below the upper structure and including a needle fixing groove formed on a lower surface thereof; and
the needle including an elastic bending portion, a tip portion extending from a lower end of the elastic bending portion, and a connection portion extending from an upper end of the elastic bending portion and connected electrically to the probe circuit pattern,
wherein a distance between a outmost portion of the elastic bending portion and an tip portion axis is greater than a distance between the outmost portion of the elastic bending portion and an axis corresponding to the connection portion.

11. The structure of claim 10, wherein the upper structure has a guide hole through which the connection portion passes, and the guide hole is connected to the needle fixing groove.

12. The structure of claim 11, wherein at least a part of a changeover portion for connecting the connection portion to the elastic bending portion is received in the needle fixing groove.

13. The structure of claim 10, wherein the upper structure has a guide hole through which the connection portion passes, and the guide hole is separately formed apart from the needle fixing groove.

14. The structure of claim 13, wherein a changeover portion for connecting the connection portion to the elastic bending portion is located below the guide hole, and at least a part of the elastic bending portion upwardly following the changeover portion is received in the needle fixing groove.
